(19) United States
(12) Patent Application Publication
(10) Pub. No.: US 2009/0108313 A1
(43) Pub. Date: Apr. 30, 2009

(54) REDUCING SHORT CHANNEL EFFECTS IN TRANSISTORS

(76) Inventors: Brian S. Doyle, Portland, OR (US); Titash Rakshit, Hillsboro, OR (US)

Correspondence Address: COOL PATENT, P.C.;c/o CPA Global, P.O. BOX 52050, MINNEAPOLIS, MN, 55402, US

(21) Appl. No.: 11/877,992

(22) Filed: Oct. 24, 2007

(51) Int. Cl. H01L 27/108; H01L 21/8242

(52) U.S. Cl. 257/300; 438/239; 257/E27.084; 257/E21.646

(57) ABSTRACT

Microelectronic structures and associated methods for reducing short channel effects in transistors are generally described. In one example, an apparatus includes a semiconductor channel, one or more transistor gates coupled with the semiconductor channel, a spacer film coupled to the one or more transistor gates, and a semiconductor material epitaxially grown (epi-growth) on the semiconductor channel wherein the epi-growth is coupled to the to the spacer film to reduce short channel effects of the one or more transistor gates by effectively increasing the transistor gate length.

### BACKGROUND

Generally, the scaling of microelectronic devices has increased detrimental short channel effects in transistors.

### BRIEF DESCRIPTION OF THE DRAWINGS

Embodiments disclosed herein are illustrated by way of example, and not by way of limitation, in the figures of the accompanying drawings in which like reference numerals refer to similar elements and in which:

FIG. 1 depicts a microelectronic structure, according to but one embodiment;

FIG. 2 depicts a microelectronic structure including a spacer film, according to but one embodiment;

FIG. 3 depicts a microelectronic structure including epitaxial channel growth, according to but one embodiment;

FIG. 4 depicts a microelectronic structure including a capacitor and contact, according to but one embodiment;

FIG. 5 is a flow diagram for a method to reduce short channel effects, according to but one embodiment; and

FIG. 6 is a diagram of an example system in which embodiments of the present invention may be used, according to but one embodiment.

It will be appreciated that for simplicity and/or clarity of illustration, elements illustrated in the figures have not necessarily been drawn to scale. For example, the dimensions of some of the elements may be exaggerated relative to other elements for clarity. Further, if considered appropriate, reference numerals have been repeated among the figures to indicate corresponding and/or analogous elements.

### DETAILED DESCRIPTION

Embodiments of reducing short channel effects in transistors are described herein. In the following description, numerous specific details are set forth to provide a thorough understanding of embodiments disclosed herein. One skilled in the relevant art will recognize, however, that the embodiments disclosed herein can be practiced without one or more of the specific details, or with other methods, components, materials, and so forth. In other instances, well-known structures, materials, or operations are not shown or described in detail to avoid obscuring aspects of the specification.

Reference throughout this specification to “one embodiment” or “an embodiment” means that a particular feature, structure or characteristic described in connection with the embodiment is included in at least one embodiment. Thus, appearances of the phrases “in one embodiment” or “in an embodiment” in various places throughout this specification are not necessarily all referring to the same embodiment. Furthermore, the particular features, structures or characteristics may be combined in any suitable manner in one or more embodiments.

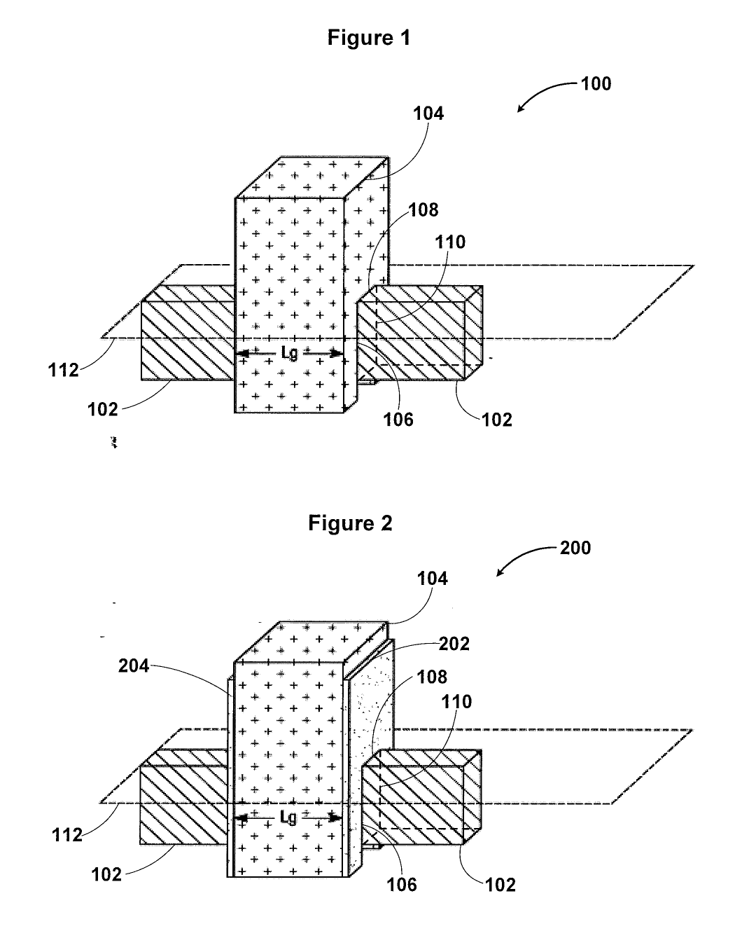

FIG. 1 depicts a microelectronic structure 100, according to but one embodiment. In an embodiment, an apparatus 100 includes a semiconductor channel 102 and a structure 104 having one or more transistor gates, each coupled as shown. In an embodiment, one or more gates 104 are part of a multi-gate transistor having a first gate 106, second gate 108, and third gate 110, each coupled as shown. An apparatus 100 may have a cell dimension 112 that depicts the area for a cell layout, which may repeat in a microelectronic device such as logic or memory device, or combination thereof. In an embodiment, one or more transistor gates 104 are part of a u-shaped tri-gate transistor. In another embodiment, one or more transistor gates 104 are part of a multi-gate dynamic random-access-memory (DRAM) access transistor.

In an embodiment, one or more transistor gates 104 have an actual gate length, Lg, as depicted. Increasing the actual gate length, Lg, may reduce short channel effects such as current leakage, but may detrimentally impact the cell dimension 112 by increasing the cell dimension 112 size. Embodiments described herein may include structures and associated methods that allow for the fabrication of transistors with low leakage, while not increasing the size of the cell 112.

In an embodiment, one or more transistor gates 104 include multiple gates. In an embodiment, structure 104 includes a first gate 106, a second gate 108, and a third gate 110. The first gate 106 may include the region of structure 104 proximate to a first side of channel 102 depicted with label 106. The second gate 108 may include the region of structure 104 proximate to a second side of channel 102 depicted with label 108. The third gate 110 may include the region of structure 104 proximate to a third side of channel 102 depicted with label 110. A third gate 110 label may point to a dashed line that represents an interface between channel 102 and structure 104 as though channel 102 is transparent for illustrative purposes. A gate dielectric material (not shown) may be coupled to structure 104 and channel 102 between structure 104 and channel 102. Structure 104 may be polysilicon according to one embodiment, but may include any other suitable material for a transistor gate.

In an embodiment, structure 104 is part of a u-shaped tri-gate transistor having three gates 106, 108, 110 wherein a first gate 104 is coupled with a first side of the channel 102, a second gate 108 is coupled with a second side of the channel 102, and a third gate 110 is coupled with a third side of the channel 102.

In an embodiment, an apparatus 100 includes a semiconductor channel 102 including silicon. In other embodiments, semiconductor channel 102 includes other suitable semiconductor materials. A channel 102 may be a positive or protruding structure such as a fin or pillar according to one embodiment. In an embodiment, a channel 102 is coupled with a source and drain to enable delivery of electrical current to structure 104.

FIG. 2 depicts a microelectronic structure including a spacer film 200, according to but one embodiment. In an embodiment, an apparatus 200 includes the features described for FIG. 1, and a thin spacer film 202, 204 coupled to the structure 104 and/or transistor gates 106, 108, 110. In an embodiment, a spacer 202, 204, is deposited after gate 106, 108, 110 formation. A spacer 202, 204 may be fabricated by conventional oxide or nitride depositions, for example silicon dioxide SiO₂ or silicon nitride (SiN), and etchbacks according to an embodiment. In another embodiment, a spacer 202, 204 is deposited by atomic layer deposition (ALD) of a high-k dielectric, followed by silicon implant and wet cleans to remove unwanted spacer material. A high-k dielectric film 202, 204 may include hafnium (Hf) or zirconium (Zr) oxides or suitable combinations thereof. A silicon implant may include an angled implant using a silicon dopant to break up the lattice structure of the spacer 202, 204 to facilitate removal of undesired spacer material. A spacer 204 may be deposited by any suitable deposition method including sputtering, ALD, physical vapor deposition (PVD), chemical vapor deposition (CVD), or suitable combinations thereof.

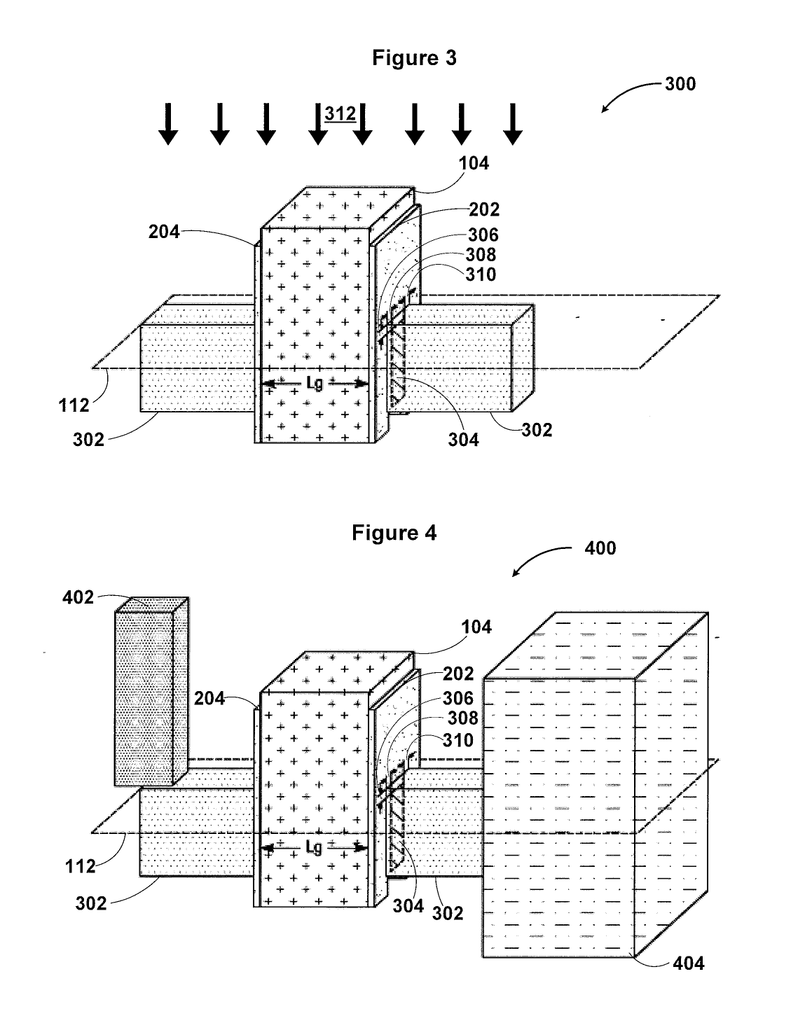

In an embodiment, a spacer 202, 204 is fabricated to limit the external resistance (Rext) of the device, which may refer to the resistance external to the channel 102, by effectively coupling the transistor gate sidewalls 106, 108, 110 to an epitaxial growth region 302 of the channel that is introduced in FIG. 3. In an embodiment, a spacer 202, 204 film includes oxide, nitride, or high-k dielectric material, or combinations thereof. In another embodiment, a spacer film 202, 204 is an ultra-thin film having a thickness less than about 50 angstroms. The spacer film 202, 204 protects against gate 106, 108, 110 shorts, according to an embodiment.

FIG. 3 depicts a microelectronic structure including epitaxial channel growth 300, according to but one embodiment. In an embodiment, an apparatus 300 includes the features described for FIGS. 1-2, and a semiconductor material epitaxially grown (epi-growth) 302 on the semiconductor channel 102 (a cross-section of which is depicted using label 304). The growth may occur on the exposed channel 102 external to structure 104. The first, second, and third sides of channel 102 as depicted in FIGS. 1-2 may be covered with epi-growth 302. The epi-growth 302 covered channel 102 may be referred to as a raised channel 304.

In an embodiment, the epi-growth 302 is coupled to the spacer film 202, 204. In another embodiment, the epi-growth 302 is effectively coupled to the spacer film 202, 204 such that the epi-growth 302 is capacitively coupled with the transistor 104 and/or gates 106, 108, 110 (as depicted in FIGS. 1-2). In another embodiment, the epi-growth 302 decreases short channel effects of the transistor structure 104 by effectively increasing the gate length of the one or more transistor gates 104. Effectively increasing the gate length of the transistor differs from actually increasing the gate length of the transistor by providing the benefits associated with increasing gate length, but without actually increasing gate length, Lg, in the direction of the Lg arrows.

In an embodiment, epi-growth 302 on the second side of channel 102 has a thickness 306 depicted as the distance between the two lines between the arrows as indicated, epi-growth 302 on the first side of channel 102 has a thickness 308 depicted as the distance between the two lines between the arrows as indicated, and epi-growth 302, on the third side of channel 102 has a thickness 310 depicted as the distance between the two lines between the arrows as indicated. In an embodiment, epi-growth 302 on the channel 102 has a first thickness 308 measured in a direction normal to the first side of the channel 102, a second thickness 306 measured in a direction normal to the second side of the channel 102, and a third thickness 310 measured in a direction normal to the third side of the channel.

In an embodiment, the transistor gate length for the first gate 106 is effectively increased by an amount about double the first thickness 308, the transistor gate length for the second gate 108 is effectively increased by an amount about double the second thickness 306, and the transistor gate length for the third gate 110 is effectively increased by an amount about double the third thickness 310. The effective increase in gate length may be about double the thickness of associated epi-growth to account for epi-growth 302 on the channel 102 on both sides of structure 104 (i.e.—the side with spacer 202 and the side with spacer 204). When considering only one side of the gate structure 104 (i.e.—the side having spacer film 202) the effective increase in gate length is about half the amount described in the embodiment above.

In another embodiment where epi-growth 302 only occurs in the direction normal to the second side of the channel 102, the gate length for the associated gate 108 is effectively increased by an amount equal to about twice the thickness 306 of the epi-growth 302 in that direction. In an embodiment, structure 104 is part of a planar transistor having a single gate.

The crystal orientation of the epi-growth 302 may be the same or about the same as the crystal orientation of the channel 102. In an embodiment, the crystal orientation of the epi-growth on the first, second, and third sides of the channel 102 is the same or about the same. In another embodiment, thicknesses 306, 308, and 310 are roughly the same. A semiconductor channel 102 may include silicon or any other suitable semiconductor material or combinations of material and epi-growth 302 may include silicon or any other suitable semiconductor material or combinations of material. A clean channel 102 surface may be required for epitaxial growth 304.

In an embodiment, an apparatus 300 receives an implant 312. An implant 312 may be a low energy source/drain implant to pull back junctions or reduce gate junction diffusion into the epitaxial growth region 302 of the channel, or combinations thereof. In an embodiment, the one or more gates 104, spacer film 202, 204, and epi-growth 302 are doped with a low energy implant. The implant 312 may be active in the epi-growth 302 and/or gate regions 104. In an embodiment, the epi-growth 302 prevents dopants from being implanted 312 at gate regions 106, 108, 110 protected by the epi-growth 302. A transistor in accordance with apparatus 300 may reduce leakage current of the transistor with only an insignificant decrease in the drive current of the device. In an embodiment, methods and apparatuses described with respect to FIGS. 1-3 allow for reducing short channel effects in a multi-gate access transistor without increasing the cell size.

FIG. 4 depicts a microelectronic structure including a capacitor and contact 400, according to but one embodiment. In an embodiment, an apparatus 400 includes the features described for FIGS. 1-3, a contact 402, and a capacitor 404, each coupled as shown. In an embodiment, one or more transistor gates 104 are part of a multi-gate DRAM access transistor cell 400 including a capacitor 404 coupled with the epi-growth or raised channel 302 and a bitline contact 402 coupled with the epi-growth or raised channel 302. A bit-line contact 502 may be shared with a cell having a cell dimension adjacent to cell dimension 112. In another embodiment, an apparatus 400 has a cell dimension 112 that is not increased by the effective gate lengthening of the epi-growth 302.

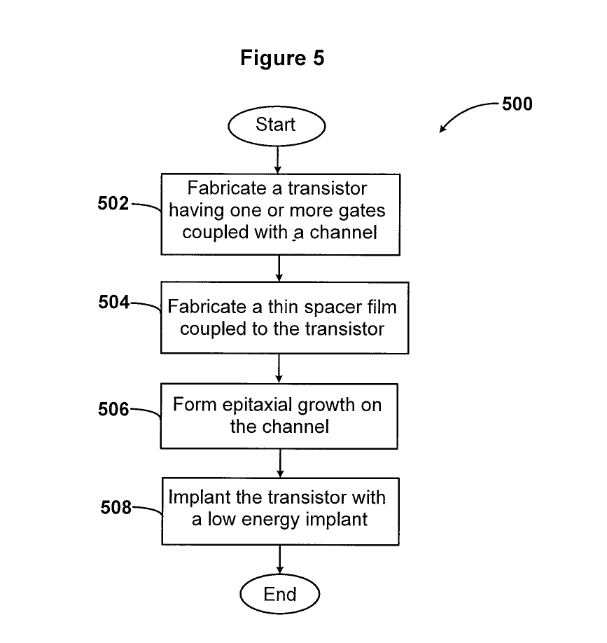

FIG. 5 is a flow diagram for a method to reduce short channel effects 500, according to but one embodiment. In an embodiment, a method 500 includes fabricating a transistor having one or more gates coupled with a channel 502, fabricating a thin spacer film coupled to the one or more transistor gates 504, forming epitaxial growth on the channel 506, and implanting the transistor with a low energy implant 508. A method 500 may accord with embodiments already described with respect to FIGS. 1-4.

In an embodiment, a method 500 includes fabricating one or more transistor gates coupled with a channel 502, fabricating a spacer film coupled to the one or more transistor gates 504, and forming epitaxial growth on the channel 506, the epitaxial growth being coupled to the spacer film wherein the epitaxial growth decreases short channel effects of the one or more transistor gates by effectively increasing the transistor gate length. In an embodiment, a method 500 includes doping 508 the exposed areas of the one or more transistor gates, spacer film, and epitaxial growth on the channel with a low energy source/drain implant. In an embodiment, implanting 508 is performed to pull back junctions or reduce gate junction diffusion into the epitaxial growth region of the channel, or combinations thereof.

Fabricating one or more transistor gates 502 may include fabricating a u-shaped tri-gate structure having three gates wherein a first gate is coupled with a first side of the channel, a second gate is coupled with a second side of the channel, and a third gate is coupled with a third side of the channel. According to an embodiment, a tip implant is not necessary and/or is not used after fabricating one or more transistor gates 502 and before fabricating a spacer film 504.

Fabricating a spacer film 504 may be performed in a variety of ways. In one embodiment, fabricating a spacer film 504 includes depositing a spacer material including oxide, nitride, or a high-k dielectric material, or combinations thereof, to the one or more transistor gates. In another embodiment, fabricating a spacer film 504 includes etching back the spacer material or applying wet cleans, or combinations thereof, to produce a spacer film of desired thickness. In an embodiment, a spacer film is very thin having a thickness less than about 50 angstroms. In an embodiment, the spacer film is used to couple the epitaxial growth to the one or more transistor gates or to protect against gate shorts, or combinations thereof.

In an embodiment, forming epitaxial growth on the channel 506 includes forming epitaxial growth having a first thickness measured in a direction normal to the first side of the channel, a second thickness measured in a direction normal to the second side of the channel, and a third thickness measured in a direction normal to the third side of the channel. In an embodiment, the transistor gate length for the first gate is effectively increased by an amount about twice the first thickness, the transistor gate length for the second gate is effectively increased by an amount about twice the second thickness, and the transistor gate length for the third gate is effectively increased by an amount about twice the third thickness.

A method 500 may also include fabricating a capacitor coupled with the channel, and/or fabricating a bitline contact coupled with the channel. In an embodiment, a capacitor, bitline contact, one or more transistor gates, and channel have a cell dimension that is not increased by forming epitaxial growth on the channel.

Various operations may be described as multiple discrete operations in turn, in a manner that is most helpful in understanding the invention. However, the order of description should not be construed as to imply that these operations are necessarily order dependent. In particular, these operations need not be performed in the order of presentation. Operations described may be performed in a different order than the described embodiment. Various additional operations may be performed and/or described operations may be omitted in additional embodiments.

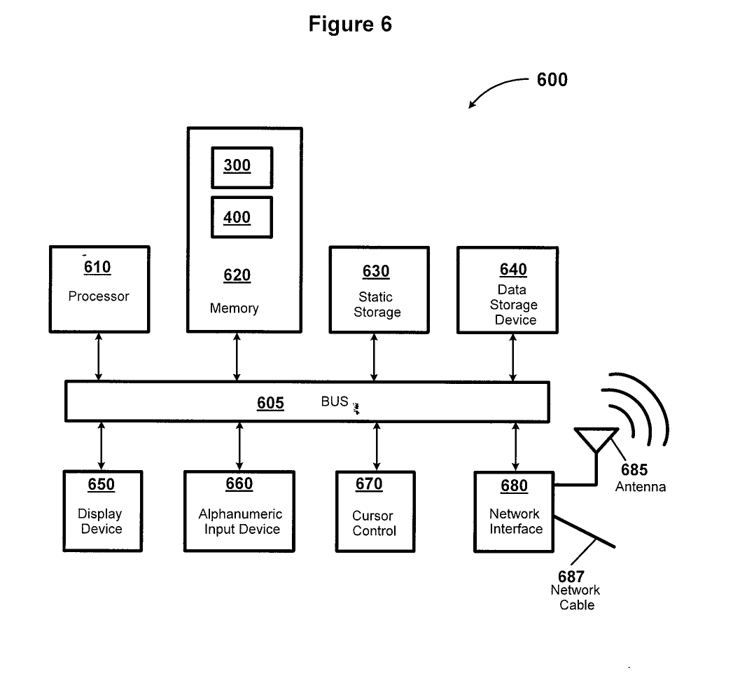

FIG. 6 is a diagram of an example system in which embodiments of the present invention may be used, according to but one embodiment. System 600 is intended to represent a range of electronic systems (either wired or wireless) including, for example, desktop computer systems, laptop computer systems, personal computers (PC), wireless telephones, personal digital assistants (PDA) including cellular-enabled PDAs, set top boxes, pocket PCs, tablet PCs, DVD players, or servers, but is not limited to these examples and may include other electronic systems. Alternative electronic systems may include more, fewer and/or different components.

In one embodiment, electronic system 600 includes a microelectronic apparatus for reducing short channel effects as described with respect to FIGS. 1-5. In an embodiment, a microelectronic apparatus 300, 400 for reducing short channel effects is part of an electronic system's memory 620 or processor 610.

Electronic system 600 may include bus 605 or other communication device to communicate information, and processor 610 coupled to bus 605 that may process information. While electronic system 600 may be illustrated with a single processor, system 600 may include multiple processors and/or co-processors. In an embodiment, processor 610 includes a microelectronic apparatus 300, 400 for reducing short channel effects in accordance with embodiments described herein. System 600 may also include random access memory (RAM) or other storage device 620 (may be referred to as memory), coupled to bus 605 and may store information and instructions that may be executed by processor 610.

Memory 620 may also be used to store temporary variables or other intermediate information during execution of instructions by processor 610. Memory 620 is a flash memory device in one embodiment. In another embodiment, memory 620 includes a microelectronic apparatus 300, 400 for reducing short channel effects as disclosed herein.

System 600 may also include read only memory (ROM) and/or other static storage device 630 coupled to bus 605 that may store static information and instructions for processor 610. Data storage device 640 may be coupled to bus 605 to store information and instructions. Data storage device 640 such as a magnetic disk or optical disc and corresponding drive may be coupled with electronic system 600.

Electronic system 600 may also be coupled via bus 605 to display device 650, such as a cathode ray tube (CRT) or liquid crystal display (LCD), to display information to a user. Alphanumeric input device 660, including alphanumeric and other keys, may be coupled to bus 605 to communicate information and command selections to processor 610. Another type of user input device is cursor control 670, such as a mouse, a trackball, or cursor direction keys to communicate information and command selections to processor 610 and to control cursor movement on display 650.

Electronic system 600 further may include one or more network interfaces 680 to provide access to network, such as a local area network. Network interface 680 may include, for example, a wireless network interface having antenna 685, which may represent one or more antennae. Network interface 680 may also include, for example, a wired network interface to communicate with remote devices via network cable 687, which may be, for example, an Ethernet cable, a coaxial cable, a fiber optic cable, a serial cable, or a parallel cable.

In one embodiment, network interface 680 may provide access to a local area network, for example, by conforming to an Institute of Electrical and Electronics Engineers (IEEE) standard such as IEEE 802.11b and/or IEEE 802.11g standards, and/or the wireless network interface may provide access to a personal area network, for example, by conforming to Bluetooth standards. Other wireless network interfaces and/or protocols can also be supported.

IEEE 802.11b corresponds to IEEE Std. 802.11b-1999 entitled “Local and Metropolitan Area Networks, Part 11: Wireless LAN Medium Access Control (MAC) and Physical Layer (PHY) Specifications: Higher-Speed Physical Layer Extension in the 2.4 GHz Band,” approved Sep. 16, 1999 as well as related documents. IEEE 802.11g corresponds to IEEE Std. 802.11g-2003 entitled “Local and Metropolitan Area Networks, Part 11: Wireless LAN Medium Access Control (MAC) and Physical Layer (PHY) Specifications, Amendment 4: Further Higher Rate Extension in the 2.4 GHz Band,” approved Jun. 27, 2003 as well as related documents. Bluetooth protocols are described in “Specification of the Bluetooth System: Core, Version 1.1,” published Feb. 22, 2001 by the Bluetooth Special Interest Group, Inc. Previous or subsequent versions of the Bluetooth standard may also be supported.

In addition to, or instead of, communication via wireless LAN standards, network interface(s) 380 may provide wireless communications using, for example, Time Division, Multiple Access (TDMA) protocols, Global System for Mobile Communications (GSM) protocols, Code Division, Multiple Access (CDMA) protocols, and/or any other type of wireless communications protocol.

In an embodiment, a system 600 includes one or more omnidirectional antennae 685, which may refer to an antenna that is at least partially omnidirectional and/or substantially omnidirectional, and a processor 610 coupled to communicate via the antennae.

The above description of illustrated embodiments, including what is described in the Abstract, is not intended to be exhaustive or to limit to the precise forms disclosed. While specific embodiments and examples are described herein for illustrative purposes, various equivalent modifications are possible within the scope of this description, as those skilled in the relevant art will recognize.

These modifications can be made in light of the above detailed description. The terms used in the following claims should not be construed to limit the scope to the specific embodiments disclosed in the specification and the claims. Rather, the scope of the embodiments disclosed herein is to be determined entirely by the following claims, which are to be construed in accordance with established doctrines of claim interpretation.

What is claimed is:

1. An apparatus comprising:
a semiconductor channel;
one or more transistor gates coupled with the semiconductor channel;
a spacer film coupled to the one or more transistor gates; and
a semiconductor material epitaxially grown (epi-growth) on the semiconductor channel wherein the epi-growth is coupled to the to the spacer film to effectively increase the transistor gate length to reduce short channel effects of the one or more transistor gates.

2. An apparatus according to claim 1 wherein the one or more transistor gates, spacer film, and epi-growth are doped with a low energy source/drain implant to pull back junctions or reduce gate junction diffusion into the epitaxial growth region of the channel, or combinations thereof.

3. An apparatus according to claim 1 wherein the spacer film comprises oxide, nitride, or high-k dielectric material, or combinations thereof, the spacer film having a thickness less than about 50 angstroms, and wherein the spacer film couples the epi-growth to the one or more gates or protects against gate shorts, or combinations thereof.

4. An apparatus according to claim 1 wherein the one or more transistor gates are part of a u-shaped tri-gate transistor having three gates wherein a first gate is coupled with a first side of the channel, a second gate is coupled with a second side of the channel, and a third gate is coupled with a third side of the channel.

5. An apparatus according to claim 4 wherein the epi-growth on the channel has a first thickness measured in a direction normal to the first side of the channel, a second thickness measured in a direction normal to the second side of the channel, and a third thickness measured in a direction normal to the third side of the channel wherein the transistor gate length for the first gate is effectively increased by an amount about twice the first thickness, the transistor gate length for the second gate is effectively increased by an amount about twice the second thickness, and the transistor gate length for the third gate is effectively increased by an amount about twice the third thickness.

6. An apparatus according to claim 5 wherein the epi-growth on the first, second, and third sides of the channel have the same, or nearly the same, crystal orientation and wherein the first, second, and third thicknesses are the same, or nearly the same.

7. An apparatus according to claim 1 wherein the semiconductor channel comprises silicon and wherein the epi-growth comprises silicon.

8. An apparatus according to claim 1 wherein the one or more transistor gates are part of a multi-gate DRAM access transistor, the apparatus further comprising:
a capacitor coupled with the channel; and
a bitline contact coupled with the channel wherein the capacitor, bitline contact, one or more transistor gates, and channel have a cell dimension that is not increased, or substantially not increased, by the effective gate lengthening of the epi-growth.

9. A method comprising:
fabricating one or more transistor gates coupled with a channel;
fabricating a spacer film coupled to the one or more transistor gates; and
forming epitaxial growth on the channel, the epitaxial growth being coupled to the spacer film wherein the epitaxial growth effectively increases the transistor gate length to reduce short channel effects of the one or more transistor gates.

10. A method according to claim 9 further comprising:
doping the exposed areas of the one or more transistor gates, spacer film, and epitaxial growth on the channel with a low energy source/drain implant to pull back junctions or reduce gate junction diffusion into the epitaxial growth region of the channel, or combinations thereof.

11. A method according to claim 9 wherein fabricating a spacer film coupled to the one or more transistor gates comprises:
depositing a spacer material comprising oxide, nitride, or high-k dielectric material, or combinations thereof, to the one or more transistor gates;
etching back the spacer material, implanting the spacer material using silicon to break up the lattice structure of the spacer material, or applying wet cleans, or combinations thereof, to produce a spacer film having a thickness less than about 50 angstroms; and
using the spacer film to couple the epitaxial growth to the one or more transistor gates or to protect against gate shorts, or combinations thereof.

12. A method according to claim 9 wherein fabricating one or more transistor gates comprises fabricating a u-shaped tri-gate structure having three gates wherein a first gate is coupled with a first side of the channel, a second gate is coupled with a second side of the channel, and a third gate is coupled with a third side of the channel.

13. A method according to claim 12 wherein forming epitaxial growth on the channel comprises forming epitaxial growth having a first thickness measured in a direction normal to the first side of the channel, a second thickness measured in a direction normal to the second side of the channel, and a third thickness measured in a direction normal to the third side of the channel wherein the transistor gate length for the first gate is effectively increased by an amount about twice the first thickness, the transistor gate length for the second gate is effectively increased by an amount about twice the second thickness, and the transistor gate length for the third gate is effectively increased by an amount about twice the third thickness.

14. A method according to claim 9 wherein a tip implant is not used after fabricating one or more transistor gates and before fabricating a spacer film.

15. A method according to claim 9 further comprising:
fabricating a capacitor coupled with the channel; and
fabricating a bitline contact coupled with the channel wherein the capacitor, bitline contact, one or more transistor gates, and channel have a cell dimension that is not increased by forming epitaxial growth on the channel.
